(19) United States
(12) Patent Application Publication
(10) Pub. No.: US 2025/0008779 A1
(43) Pub. Date: Jan. 2, 2025

(54) DISPLAY PANEL, DISPLAY APPARATUS, AND METHOD FOR MANUFACTURING DISPLAY PANEL

(71) Applicant: Hefei Visionox Technology Co., Ltd., Hefei (CN)

(72) Inventors: Liusong NI, Hefei (CN); Yiming XIAO, Hefei (CN); Yuan YAO, Hefei (CN); Yi-Yu LAI, Hefei (CN); Xuejing ZHU, Hefei (CN); Yuting FU, Hefei (CN)

(73) Assignee: Hefei Visionox Technology Co., Ltd., Hefei (CN)

(21) Appl. No.: 18/673,971

(22) Filed: May 24, 2024

(30) Foreign Application Priority Data
Jun. 29, 2023 (CN) 202310791343.3

(51) Int. Cl. H10K 59/122; H10K 59/12; H10K 59/131; H10K 59/80

(52) U.S. Cl. CPC H10K 59/122; H10K 59/1201; H10K 59/131; H10K 59/873

(57) ABSTRACT

A display panel, a display apparatus, and a method for manufacturing a display panel. The display panel includes a base plate, an isolation structure, a light-emitting functional layer, and a plurality of first electrodes, the isolation structure includes a first portion and a second portion; the light-emitting functional layer includes first light-emitting portions and second light-emitting portions; an edge of the first electrode overlaps the first portion, a shortest connecting line between an edge of the first electrode portion and the first edge is a first connecting line, a shortest connecting line between an edge of the second electrode portion and the second edge is a second connecting line, and an angle between the second connecting line and a plane in which the base plate is located is less than an angle between the first connecting line and the plane.

### CROSS REFERENCE TO RELATED APPLICATION

The present application claims priority to Chinese Patent Application No. 202310791343.3 filed on Jun. 29, 2023, which is incorporated herein by reference in its entirety.

### TECHNICAL FIELD

The present application relates to the field of display technology, and particularly to a display panel, a display apparatus, and a method for manufacturing a display panel.

### BACKGROUND

Display panels based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus. However, the current manufacturing process for the display panels needs to be improved.

### SUMMARY

Embodiments of the present application provide a display panel, a display apparatus, and a method for manufacturing a display panel, aiming to solve technical problems in the manufacturing process of the related display panel.

Some embodiments of a first aspect of the present application provide a display panel, including: a base plate; an isolation structure arranged at a side of the base plate, the isolation structure enclosing and forming a plurality of first openings and a plurality of second openings, the isolation structure including a first portion and a second portion that are stacked, the first portion being arranged at a side of the second portion close to the base plate, an orthographic projection of the first portion on the base plate being located within an orthographic projection of the second portion on the base plate, the second portion including a partition edge, an orthographic projection of the partition edge on the base plate being located at an edge of the orthographic projection of the second portion on the base plate, and the partition edge including a first edge defining the first opening and a second edge defining the second opening; a light-emitting functional layer including a plurality of first light-emitting portions and a plurality of second light-emitting portions, at least a portion of the first light-emitting portion being arranged within the first opening, at least a portion of the second light-emitting portion being arranged within the second opening, and a wavelength of a light wave emitted by the first light-emitting portion being different from a wavelength of a light wave emitted by the second light-emitting portion; and a plurality of first electrodes located at a side of the light-emitting functional layer away from the base plate, an edge of the first electrode overlapping a side surface of the first portion facing the define opening, the plurality of first electrodes including a first electrode portion arranged at a side corresponding to the first light-emitting portion and a second electrode portion arranged at a side corresponding to the second light-emitting portion, a shortest connecting line between an edge of the first electrode portion and the first edge being a first connecting line, a shortest connecting line between an edge of the second electrode portion and the second edge being a second connecting line, and an angle between the second connecting line and a plane in which the base plate is located being less than an angle between the first connecting line and the plane in which the base plate is located.

Some embodiments of a second aspect of the present application provide a method for manufacturing a display panel, including: providing a base plate; forming an isolation structure at a side of the base plate, the isolation structure enclosing and forming a plurality of define openings, the define openings including first openings and second openings, the isolation structure including a first portion and a second portion that are stacked, the first portion being arranged at a side of the second portion close to the base plate, an orthographic projection of the first portion on the base plate being located within an orthographic projection of the second portion on the base plate, the second portion including a partition edge, an orthographic projection of the partition edge on the base plate being located at an edge of the orthographic projection of the second portion on the base plate, and the partition edge including a first edge defining the first opening and a second edge defining the second opening; and forming a light-emitting functional layer and a plurality of first electrodes, the light-emitting functional layer including a first light-emitting portion and a second light-emitting portion, at least a portion of the first light-emitting portion being arranged within the first opening, and at least a portion of the second light-emitting portion being arranged within the second opening; and the plurality of first electrodes including a first electrode portion and a second electrode portion arranged at a side corresponding to the second light-emitting portion, a shortest connecting line between an edge of the first electrode portion and the first edge being a first connecting line, a shortest connecting line between an edge of the second electrode portion and the second edge being a second connecting line, and an angle between the second connecting line and a plane in which the base plate is located being less than an angle between the first connecting line and the plane in which the base plate is located.

Some embodiments of a third aspect of the present application provide a display apparatus including the display panel of any one of the above implementations, or a display panel manufactured by the method of any one of the above implementations.

In the display panel, the display apparatus, and the method for manufacturing a display panel according to the embodiments of the present application, with the isolation structure, the light-emitting portion and the first electrode at least partially located within the define opening can be prepared without a metal mask plate, thereby eliminating the process and expense of the metal mask plate, and thus the manufacturing process of the display panel is optimized, the manufacturing efficiency of the display panel in increased, and cost of manufacturing the display panel is reduced. With the angle between the second connecting line and the plane in which the base plate is located being less than the angle between the first connecting line and the plane in which the base plate is located, it is ensured that the edge of the first electrode formed by vapor deposition can overlap the first portion.

### BRIEF DESCRIPTION OF THE DRAWINGS

Other features, objects and advantages of the present application will be more apparent from reading the following detailed description of non-limiting embodiments with reference to the accompanying drawings, in which the same or similar reference numerals denote the same or similar features, and the accompanying drawings are not drawn to actual scale.

FIG. 1 shows a partial top view of a display panel according to an embodiment of the present application;

FIG. 2 shows a partial sectional view of a display panel according to an embodiment of the present application;

FIG. 3 shows a partial sectional view of a display panel according to another embodiment of the present application;

FIG. 4 shows a partial sectional view of a display panel according to yet another embodiment of the present application;

FIG. 5 shows a partial sectional view of a display panel according to yet another embodiment of the present application;

FIG. 6 shows a partial sectional view of a display panel according to yet another embodiment of the present application;

FIG. 7 shows a partial sectional view of a display panel according to yet another embodiment of the present application;

FIG. 8 shows a partial sectional view of a display panel according to yet another embodiment of the present application;

FIG. 9 shows a process diagram of a method for manufacturing a display panel according to an embodiment of the present application;

FIG. 10 shows a process diagram of a method for manufacturing a display panel according to an embodiment of the present application.

### REFERENCE NUMERALS

1, base plate; 11, substrate; 12, planarization layer; 13, array base plate; 131, active layer; 132, gate; 133, drain; 137, source; 135, first electrode plate; 136, second electrode plate; 2, first electrode; 21, first electrode portion; 22, second electrode portion; 23, third electrode portion; 3, isolation structure; 31, first portion; 311, first sub-portion; 312, second sub-portion; 32, second portion; 321, partition edge; 33, define opening; 331, first opening; 332, second opening; 333, third opening; 41, first light-emitting portion; 42, second light-emitting portion; 43, third light-emitting portion; 5, second electrode; 6, pixel defining layer; 71, first encapsulation layer; 72, second encapsulation layer; 73, third encapsulation layer.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that when describing the structure of a component, if a layer/area is referred to as being “on” or “above” another layer/region, it may mean that the layer/area is directly on the other layer/region or that other layers/regions may be included between the layer/area and the other layer/area. Moreover, if the component is turned over, the layer/region will be “below” or “under” the other layer/region.

In order to solve the above problems, the embodiments of the present application provide a display panel and a display apparatus, and various embodiments of the display panel and the display apparatus will be described below in connection with the accompanying drawings.

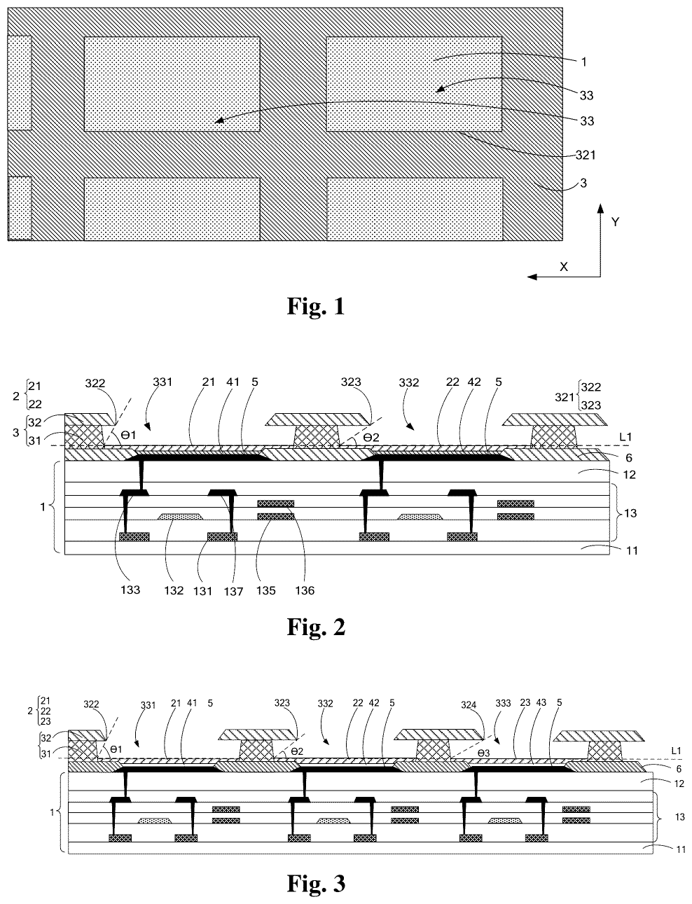

The embodiments of the present application provide a display panel, a method for manufacturing a display panel, and a display apparatus, and various embodiments of the display panel, the method for manufacturing a display panel, and the display apparatus will be described below in conjunction with FIGS. 1 to 10.

Referring to FIGS. 1 and 2, the display panel includes a base plate 1, an isolation structure 3, a light-emitting functional layer, and a plurality of first electrodes 2. The isolation structure 3 is arranged at a side of the base plate 1, the isolation structure 3 encloses and forms a plurality of define openings 33, the plurality of define openings 33 includes a first opening 331 and a second opening 332, the isolation structure 3 includes a first portion 31 and a second portion 32 that are stacked, the first portion 31 is arranged at a side of the second portion 32 close to the base plate 1, an orthographic projection of the first portion 31 on the base plate 1 is located within an orthographic projection of the second portion 32 on the base plate 1, the second portion 32 includes a partition edge 321, an orthographic projection of the partition edge 321 on the base plate 1 is located at an edge of the orthographic projection of the second portion 32 on the base plate 1, and the partition edge 321 includes a first edge 322 defining the first opening 331 and a second edge 323 defining the second opening 332. The light-emitting functional layer includes a plurality of first light-emitting portions 41 and a plurality of second light-emitting portions 42, at least a portion of the first light-emitting portion 41 is arranged within the first opening 331, at least a portion of the second light-emitting portion 42 is arranged within the second opening 332, and a wavelength of a light wave emitted by the first light-emitting portion 41 is different from a wavelength of a light wave emitted by the second light-emitting portion 42. The first electrodes 2 are located at a side of the light-emitting functional layer away from the base plate 1, an edge of the first electrode 2 overlaps a side surface of the first portion 31 facing the define opening 1, the plurality of first electrodes 2 include a first electrode portion 21 arranged at a side corresponding to the first light-emitting portion 41 and a second electrode portion 22 arranged at a side corresponding to the second light-emitting portion 42, a shortest connecting line between an edge of the first electrode portion 21 and the first edge 322 is a first connecting line, a shortest connecting line between an edge of the second electrode portion 22 and the second edge 323 is a second connecting line, and an angle θ2 between the second connecting line and a plane in which the base plate 1 is located is less than an angle θ1 between the first connecting line and the plane in which the base plate 1 is located. Herein, the shortest connecting line between the edge of the first electrode portion 21 and the first edge 322 refers to a connecting line, in a certain sectional view perpendicular to the plane in which the base plate 1 is located, between the edge of the first electrode portion 21 and the first edge 322 corresponding to the first electrode portion 21; and the shortest connecting line between the edge of the second electrode portion 22 and the second edge 323 refers to a connecting line, in a certain sectional view perpendicular to the plane in which the base plate 1 is located, between the edge of the second electrode portion 22 and the second edge 323 corresponding to second electrode portion 22.

The display panel according to the embodiments of the present application may be a display panel based on Organic Light Emitting Diode (OLED) technology. In the display panel according to the embodiments of the present application, the base plate 1 can not only provide a support force for the isolation structure 3, but also provide an electrical signal for the first electrode 2. The base plate 1 may be arranged in various forms. In some embodiments, the base plate 1 may include a substrate 11 and an array base plate 13 arranged on the substrate 11, and the array base plate 13 may include a pixel driving circuit, and a first electrically conductive layer, a second electrically conductive layer, a third electrically conductive layer, a fourth electrically conductive layer, and the like that are stacked. Exemplarily, the pixel driving circuit arranged in the array base plate 13 includes a transistor and a storage capacitor. The transistor includes an active layer 131, a gate 132, a drain 133, and a source 137. The storage capacitor includes a first electrode plate 135 and a second electrode plate 136. As an example, the gate 132 and the first electrode plate 135 may be located in the third electrically conductive layer, the second electrode plate 136 may be located in the second electrically conductive layer, and the drain 133 and the source 137 may be located in the first electrically conductive layer.

Those skilled in the art may understand that in order to enable the display panel to emit lights of different colors, light-emitting portions for emitting lights of different colors should be prepared, and the isolation structure 3 is arranged among the various light-emitting portions. The light-emitting portions emitting lights of different colors may be prepared in steps, i.e., a plurality of first light-emitting portions 41 for emitting light of a first color are first prepared, then a plurality of second light-emitting portions 42 for emitting light of a second color are prepared, and so on, until the light-emitting portions for emitting lights of different colors are all prepared. In the present application, the light-emitting portions for emitting lights of different colors includes a first light-emitting portion 41 and a second light-emitting portion 42, in which “first” and “second” are only used to distinguish the light-emitting portions, without necessarily requiring or implying that the light-emitting functional layer in the solution of the present application consists of the first light-emitting portion 41 and the second light-emitting portion 42 which emit lights of two colors. The solution of the present application may further include light-emitting portions for emitting lights of a third, fourth, fifth . . . colors. The wavelength of the light wave emitted by the first light-emitting portion 41 is different from the wavelength of the light wave emitted by the second light-emitting portion 42, which may be understood as the light of a first color emitted by the first light-emitting portion 41 and the light of a second color emitted by second light-emitting portion 42 being of different colors.

The isolation structure 3 encloses and forms the define openings 33 to define the range for arranging the light-emitting functional layer. The isolation structure 3 includes the first portion 31 and the second portion 32 that are stacked, and the orthographic projection of the first portion 31 on the base plate 1 is located within the orthographic projection of the second portion 32 on the base plate 1, so that the cross-sectional area of an end of the isolation structure 3 away from the base plate 1 is large, and the cross-sectional area of an end of the isolation structure 3 close to the base plate 1 is small. The second portion 32 completely blocks the first portion 31 along the direction from the isolation structure 3 to the base plate 1. The define openings 33 may be in one-to-one correspondence with the light-emitting portions, and under a condition that the light-emitting functional layer includes a plurality of light-emitting portions, the plurality of define openings 33 may include openings that are in one-to-one correspondence with the various light-emitting portions. The shapes and sizes of the first opening 331 and the second opening 332 may be the same or different.

When preparing the light-emitting portions, the light-emitting material A for preparing the first light-emitting portion 41 may be coated on the isolation structure 3 using vapor deposition technique. Since the second portion 32 blocks the first portion 31, the light-emitting material A for preparing the first light-emitting portion 41 has a large drop at the partition edge 321 of the second portion 32, and it is difficult for the light-emitting material A falling within the define opening 33 to be connected with the light-emitting material A falling on the second portion 32, and thus fracture occurs, resulting in that the light-emitting material A is divided within adjacent define openings 33. The light-emitting material A falling on the second portion 32 and the light-emitting material A falling within the define openings 33 other than the first opening 331 (e.g., the light-emitting material A falling within the second opening 332) may be removed as needed. The light-emitting material B for preparing the second light-emitting portion 42 may be coated on the isolation structure 3 using vapor deposition technique. Similarly, since the second portion 32 blocks the first portion 31, the light-emitting material B for preparing the second light-emitting portion 42 has a large drop at the partition edge 321 of the second portion 32, and it is difficult for the light-emitting material B falling within the define opening 33 to be connected with the light-emitting material B falling on the second portion 32, and thus fracture occurs, resulting in the light-emitting material B is divided within adjacent define openings 33. The light-emitting material B falling on the second portion 32 and the light-emitting material B falling within the define openings 33 other than the second opening 332 (e.g., the light-emitting material B falling within the first opening 331) may be removed as needed. In this manner, light-emitting portions capable of emitting lights of different colors are sequentially prepared, until a light-emitting functional layer including a plurality of light-emitting portions is prepared.

Therefore, compared with the prior art in which the vapor deposition of the light-emitting functional layer is implemented through a mask plate, the present application arranges the first portion 31 and the second portion 32, so that the light-emitting portion located within the define opening 33 can be prepared without a mask plate, thereby eliminating the cost of preparing the mask plate. Compared with preparing a mask plate with high accuracy, it is easier to directly prepare the isolation structure 3 with high accuracy, and thus the structure of the display panel in the present application has low requirements for the preparation process, and the manufactured display panel has great consistency.

When preparing the first electrode 2, the electrically conductive material C for preparing the first electrode 2 may be coated on the isolation structure 3 and the light-emitting functional layer using vapor deposition technique. The electrically conductive material C for preparing the first electrode 2 has a large drop at the partition edge 321, and it is difficult for the electrically conductive material C falling within the define opening 33 to be connected with the electrically conductive material C falling on the second portion 32, and thus fracture occurs, resulting in the first electrode 2 that is divided. The electrically conductive material C falling on the second portion 32 may be removed as needed. At least a portion of the first electrode 2 is located within the define opening 33. Under a condition the first portion 31 is at least partially electrically conductive, the first electrode 2 may overlap the electrically conductive area of the first portion 31 to supply power to the first electrode 2, and moreover, adjacent first electrodes 2 are electrically connected, thereby forming a planar electrode that is totally electrically conductive.

Under a condition that one or more light-emitting portions have been prepared, unwanted light-emitting materials and conductive materials within a portion of the define openings 33 should be removed before vapor deposition of further light-emitting portions, and the removing may cause the first portion 31 that is in contact with the removed light-emitting materials and removed conductive materials to be etched, and thus the size of the first portion 31 becomes smaller. In the embodiments of the present application, the vapor depositions the first electrodes 2 located on different light-emitting portions are implemented at different vaporizing angles, so that the electrically conductive material C forming the first electrode 2 can pass through the second light-emitting portion 42 into the define opening 33 and overlap the first portion 31 with a smaller size. In the manufactured display panel, the angle θ2 between the second connecting line and the plane in which the base plate 1 is located is less than the angle θ1 between the first connecting line and the plane in which the base plate 1 is located. As shown in FIG. 2, the dashed line L1 denotes a reference line parallel to the plane in which the base plate 1 is located, each of the vertices of the angle θ1 and the angle θ2 is the connecting point between a surface of the first electrodes 2 away from the base plate 1 and the first portion 31, and θ2<θ1.

Exemplarily, the light-emitting material A of the first light-emitting portion 41 is vaporized into both the first opening 331 and the second opening 332, and the electrically conductive material C is vaporized at a first vaporizing angle, a layer of the electrically conductive material C is formed on the light-emitting material A; the light-emitting material A and the electrically conductive material C located in the second opening 332 are removed, which causes the first portion 31 defining the second opening 332 being partially etched, and an angle between the shortest connecting line, which is between an edge of an end of the partially etched first portion 31 close to the base plate 1 and the partition edge 321, and the plane in which the base plate 1 is located is reduced. The light-emitting material B of the second light-emitting portion 42 is vaporized into the second opening 332, and the electrically conductive material C is vaporized at a second vaporizing angle which is greater than the first vaporizing angle, so as to ensure that the electrically conductive material C within the second opening 332 can overlap the first portion 31.

In the solution of the present application, with the isolation structure 3, the light-emitting portion and the first electrode 2 at least partially located within the define opening 33 can be prepared without a metal mask plate, thereby eliminating the process and expense of the metal mask plate, and thus the manufacturing process of the display panel is optimized, the manufacturing efficiency of the display panel in increased, and cost of manufacturing the display panel is reduced. With the angle θ2 between the second connecting line and the plane in which the base plate 1 is located being less than the angle θ1 between the first connecting line and the plane in which the base plate 1 is located, it is ensured that the edge of the first electrode 2 formed by vapor deposition can overlap the first portion 31.

As shown in FIG. 1, in some optional embodiments, the isolation structure 3 extends along the first direction X and the second direction Y to be a mesh in shape, and the first direction X intersects the second direction Y.

The isolation structure 3 being a mesh in shape means that the isolation structure 3 extends in the first direction X and the second direction Y, and the portion extending along the first direction X and the portion extending along the second direction Y are intersected and interconnected to form a plurality of mesh spaces, the base plate 1 is exposed from the mesh spaces, and both a second electrode 5 and the light-emitting functional layer may be located in the mesh space, so that the isolation structure 3 may be arranged surrounding the second electrode 5 and the light-emitting functional layer. That is, the second electrode 5, the light-emitting functional layer, and the first electrode 2 are separated by the isolation structure 3 in both the first direction X and the second direction Y. It should be noted that, alternatively, the orthographic projection of the isolation structure 3 on the base plate may include independent rings, which is not limited herein.

Referring to FIG. 3, in some embodiments, the plurality of define openings 33 further include a third opening 333, the light-emitting functional layer further includes a plurality of third light-emitting portions 43, at least a portion of the third light-emitting portion 43 is arranged within the third opening 333, and the partition edge further includes a third edge 324 defining the third opening 333.

The plurality of first electrodes 2 include a third electrode portion 23 arranged at a side corresponding to the third light-emitting portion 43, a shortest connecting line between an edge of the third electrode portion 23 and the third edge 324 is a third connecting line, and an angle θ3 between the third connecting line and the plane in which the base plate 1 is located is less than the angle θ2 between the second connecting line and the plane in which the base plate 1 is located. Herein, the shortest connecting line between the edge of the third electrode portion 23 and the third edge 324 refers to a connecting line, in a certain sectional view perpendicular to the plane in which the base plate 1 is located, between the edge of the third electrode portion 23 and the third edge 324 corresponding to the first electrode portion 23. It should be noted that all the connecting lines described in the present application are straight lines.

The wavelength of the light wave emitted by the first light-emitting portion 41, the wavelength of the light wave emitted by the second light-emitting portion 42, and the wavelength of the light wave emitted by the third light-emitting portion 43 are different, and the first light-emitting portion 41, the second light-emitting portion 42, and the third light-emitting portion 43 may be a red light-emitting portion emitting red light, a green light-emitting portion emitting green light, and a blue light-emitting portion emitting blue light, respectively. During preparation, the first light-emitting portion 41, the second light-emitting portion 42, and the third light-emitting portion 43 may be sequentially vapor deposited, and the first electrode 2 stacked with the first light-emitting portion 41, the first electrode 2 stacked with the second light-emitting portion 42, and the first electrode 2 stacked with the third light-emitting portion 43 may be vapor deposited using vaporizing angles that are progressively increased, so that the prepared first electrodes 2 satisfy θ3<θ2<θ1.

The first portion 31 and the second portion 32 may form a one-piece integrated structure, or alternatively, the first portion 31 and the second portion 32 may be layer structures prepared layer by layer using the same material or different materials.

Exemplarily, the first portion 31 and the second portion 32 form a one-piece integrated structure. When preparing the isolation structure 3, a material D for preparing the isolation structure 3 may be first arranged on the base plate 1, and then be patterned to collectively form the first portion 31 and the second portion 32 blocking the first portion 31. In a sectional structural diagram along the direction from the base plate 1 to the light-emitting functional layer, the cross-section of the isolation structure 3 may be a trapezoid in shape, of which the top edge faces the base plate 1.

Exemplarily, as shown in FIG. 3, the first portion 31 and the second portion 32 are layer structures prepared layer by layer. When preparing the isolation structure 3, a material E for preparing the first portion 31 may be first arranged on the base plate 1, then a material F for preparing the second portion 32 may be arranged on the material E for preparing the first portion 31, and then the materials E and F may be patterned to form the first portion 31 and the second portion 32 blocking the first portion 31.

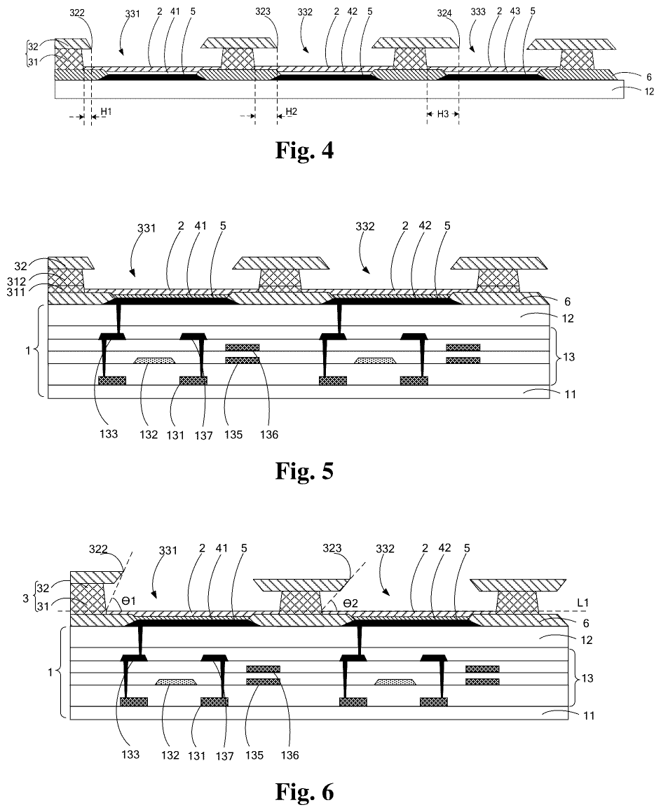

Referring to FIG. 4, in some embodiments, a minimum distance between an orthographic projection of the first edge 322 on the base plate 1 and the orthographic projection of the first portion 31 on the base plate 1 is H1, a minimum distance between an orthographic projection of the second edge 323 on the base plate 1 and the orthographic projection of the first portion 31 on the base plate 1 is H2, and H1<H2.

When manufacturing the display panel, the first light-emitting portion 41 and the first electrode 2 located within the first opening 331 may be first prepared, and then the second light-emitting portion 42 and the first electrode 2 located within the second opening 332 may be prepared. In the above preparing process, since the first light-emitting portion 41 is first prepared, the removing of the light-emitting material and the electrically conductive material located within the second opening 332 partially etches the first portion 31 defining the second opening 332, and thus H1<H2.

Under a condition that the light-emitting functional layer includes the third light-emitting portion 43, the partition edge 321 includes the third edge 324 defining the third opening 333, a minimum distance between an orthographic projection of the third edge 324 on the base plate 1 and the orthographic projection of the first portion 31 on the base plate 1 is H3, and H1<H2<H3.

Referring to FIG. 5, in some embodiments, in a direction perpendicular to the plane in which the base plate 1 is located, a cross-section of the second portion 32 is a trapezoid in shape.

Optionally, the cross-section of the second portion 32 is a trapezoid of which the bottom edge faces the base plate 1, such that the second portion 32 has a sloping surface, which facilitates the disconnection of the preparation material at the partition edge 321, and thus a portion of the preparation material is located on the second portion 32, and a portion of the preparation material is located in the define opening 33. Referring to FIG. 6, the cross-section of the second portion 32 is a trapezoid of which the top edge faces the base plate 1. The first edge 322 and the second edge 323 are located at the junction of the bottom edge and the side edge of the trapezoidal cross-section.

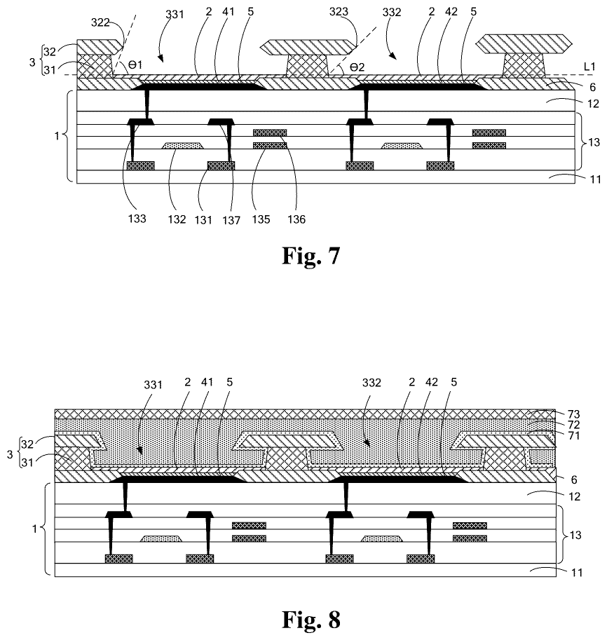

The cross-section of the second portion 32 may have other shapes. Referring to FIG. 7, the cross-section of the second portion 32 in the embodiment is a hexagon in shape, and the first edge 322 and the second edge 323 are located at the junction of two side edges of the hexagonal cross-section.

Referring to FIG. 5, in some embodiments, an area of an orthographic projection of a surface of the second portion 32 away from the base plate 1 on the base plate 1 is less than an area of an orthographic projection of a surface of the second portion 32 close to the base plate 1 on the base plate 1.

The second portion 32 extends outwardly by a preset distance with respect to the first portion 31, i.e., the area of the orthographic projection of the surface of the second portion 32 away from the base plate 1 on the base plate 1 is less than the area of the orthographic projection of the surface of the second portion 32 close to the base plate 1 on the base plate 1, as described above, such that the second portion 32 has an inclined slope structure so as to facilitate defining the pattern of the light-emitting functional layer by the second portion 32.

Under a condition that the cross-section of the second portion 32 is a trapezoid in shape and the surface of the second portion 32 away from the base plate 1 is smaller than the surface of the second portion 32 close to the base plate 1, the partition edge 321 is the periphery of the surface of the second portion 32 close to the base plate 1.

In some optional embodiments, the first portion 31 has a single-layer metal structure. For example, the first portion 31 may include only a layer of aluminum, and side surfaces of the aluminum are connected to the first electrode 2.

Alternatively, according to actual requirement, the first portion 31 may have a multi-layer metal structure. For example, referring to FIG. 5, the first portion 31 may include a first sub-portion 311 and a second sub-portion 312 that are stacked, the first sub-portion 311 includes molybdenum or titanium, and the second sub-portion 312 includes aluminum. The first electrode 2 may overlap at least one of the first sub-portion 311 or the second sub-portion 312, so as to ensure that adjacent first electrodes 2 can be electrically connected through the isolation structure 3.

Optionally, the etch rate of molybdenum and titanium is low to enable the first sub-portion 311 to extend outwardly with respect to the second sub-portion 312, and the cross-section of the first portion 31 is a trapezoid in shape, which facilitates the overlapping with the first electrode 2 that is vapor deposited. Under a condition that both the first sub-portion 311 and the second sub-portion 32 are prepared using titanium, the preparation process can be simplified.

In some optional embodiments, the area of the orthographic projection of the surface of the second portion 32 facing the base plate 1 on the base plate 1 is greater than the area of the orthographic projection of the surface of the first portion 31 away from the base plate 1 on the base plate 1. That is, the second portion 32 extends outwardly with respect to the first portion 31, so as to define the pattern of the first electrode 2 and the light-emitting functional layer by the second portion 32. The second portion 32 has an area greater than the area of the first portion 31 and is arranged completely covering the first portion 31, and in such case, the first portion 31 is recessed with respect to the second portion 32 in a direction away from the define opening 33. When preparing the second electrode 5, the second electrode 5 generates a large drop at the edge of the isolation structure 3 and the first portion 31 is arranged concavely, it is difficult for the second electrodes 5 to be connected at the outer side of the isolation structure 3, and thus fracture occurs, resulting in second electrodes 5 that are isolated from each other.

In some optional embodiments, in the direction perpendicular to the plane in which the base plate 1 is located, a cross-section of the first portion 21 is a trapezoid in shape.

The cross-section of the first portion 31 is an isosceles trapezoid in shape, which increases the contact area between the first electrode 2 and the first portion 31, so as to ensure stable overlapping between the first electrode 2 and the first portion 31. If the cross-section of the first portion 31 is an isosceles trapezoid in shape, on the one hand, the second portion 32 can be stably supported, and on the other hand, the contact area between the first sub-portion 311 and the second portion 32 is small, so that the first portion 31 is arranged concavely with respect to the second portion 32 in a direction away from the center axis of the define opening 33, facilitating disconnection of the second electrode 5 and the light-emitting functional layer at the isolation structure 3.

In these optional embodiments, in order to obtain the first portion 31 that is arranged concavely, during the etching process, the second sub-portion 312 has a greater etch rate than the first sub-portion 311 or the second portion 32, thereby forming the concave first portion 31. Due to the greater etch rate of the second sub-portion 312, more waste material generated by the etching is likely to enter other locations of the display panel, which may cause adverse effect. An orthographic projection of the second sub-portion 312 on the base plate 1 is arranged within an orthographic projection of the first sub-portion 311 on the base plate 1, so that the second sub-portion 312 can be better supported on the first sub-portion 311, and the waste material generated by the etching falls on the first sub-portion 311, which is easy to be cleaned up.

Optionally, the orthographic projection of the second portion 32 on the base plate 1 coincides with the orthographic projection of the first sub-portion 311 on the base plate 1. The first sub-portion 311 and the second portion 32 of the same area can be etched using the same mask plate, and thus the preparation process is simplified.

Referring to FIG. 8, in some embodiments, the display panel further includes a pixel defining layer 6 arranged between the base plate 1 and the isolation structure 3, the pixel defining layer 6 includes a plurality of pixel openings, and an orthographic projection of the pixel opening on the base plate 1 is located within an orthographic projection of the define opening 33 on the base plate 1.

In the embodiment, the pixel defining layer 6 is arranged on the base plate 1 and includes a plurality of pixel openings, and the light-emitting functional layer is at least partially arranged within the pixel openings, so as to enable the display panel to emit light and display.

The isolation structure 3 may be arranged directly at a side of the pixel defining layer 6 away from the base plate 1 and supported by the pixel defining layer 6.

In some embodiments, the orthographic projection of the pixel opening on the base plate 1 is located within the orthographic projection of the define opening 33 on the base plate 1. The area of the define opening 33 is greater than the area of the pixel opening, so as to reduce the effect of the isolation structure 3 on the light-emitting angle of the light-emitting functional layer.

In some embodiments, the plurality of pixel openings are distributed at intervals, and the light-emitting functional layer is arranged within each of the pixel openings.

In some embodiments, the base plate 1 further includes a planarization layer 12 supporting the pixel defining layer 6, and the planarization layer 12 provides a preparation plane for the pixel defining layer 6 to facilitate the preparation of the pixel defining layer 6. The material of the planarization layer 12 may be hexamethyl disiloxane, epoxy resin or polyimide, or other inorganic materials, which is not limited in the embodiment.

It should be noted that, according to actual requirement, the isolation structure 3 of the present application may be arranged directly on the planarization layer 12, which is not limited in the embodiment.

In some embodiments, the display panel further includes a plurality of second electrodes 5. The plurality of second electrodes 5 may be arranged at intervals, and the second electrode 5, the light-emitting functional layer, and the first electrode 2 are stacked in sequence along the direction from the base plate 1 to the light-emitting functional layer. The plurality of second electrodes 5 form a plurality of point electrodes, so that different electrical signals can be input to the plurality of second electrodes 5 to control whether the light-emitting functional layer in contact with the second electrode 5 emits light and the light-emitting duration.

One of the second electrode 5 and the first electrode 2 may be used as an anode electrode, and the other may be used as a cathode electrode. The second electrode 5, the light-emitting functional layer, and the first electrode 2 may be stacked in sequence and in contact, so that the second electrode 5, the light-emitting functional layer, and the first electrode 2 are electrically connected. Optionally, the second electrode 5 is an anode electrode and the first electrode 2 is a cathode electrode.

In the embodiments of the present application, for example, the second electrode 5 is an anode and the first electrode 2 is a cathode. The light-emitting functional layer may include one or more of an electron injection layer, an electron transmission layer, a light-emitting material layer, a hole blocking layer, an electron blocking layer, a hole transmission layer, and a hole injection layer, which may be selected according to the specific type of the light-emitting functional layer and not limited herein. The electron injection layer, the electron transmission layer, and the hole blocking layer may be arranged between the second electrode 5 and the light-emitting material layer. The electron blocking layer, the hole transmission layer, and the hole injection layer may be arranged between the first electrode 2 and the light-emitting material layer.

The material of the second electrode 5 is generally a high work function material to improve the hole injection efficiency, and may be gold (Au), platinum (Pt), titanium (Ti), silver (Ag), indium tin oxide (ITO), indium zinc oxide (IZO), or a transparent electrically conductive polymer such as polyaniline. For example, the second electrode 5 may be made of an ITO-Ag-ITO composite material, which is not limited.

The material of the first electrode 2 may be one of the metal materials such as silver (Ag), aluminum (Al), lithium (Li), magnesium (Mg), ytterbium (Yb), calcium (Ca), or indium (In), or an alloy thereof such as a magnesium-silver alloy (Mg/Ag), a lithium-aluminum alloy (Li/Al), which is not limited in the embodiment.

In some embodiments, the display panel further includes a first encapsulation layer 71 covering a side of the first electrode 2 away from the base plate 1 and in contact with a side wall of the isolation structure 3 facing the define opening 33. The first encapsulation layer 71 can prevent water vapor and the like from entering the light-emitting functional layer, and further avoid or reduce the failure of the light-emitting functional layer due to mechanical external forces, and thus the reliability of the display panel is improved.

In some embodiments, the display panel further includes a second encapsulation layer 72 located at a side of the first encapsulation layer 71 away from the base plate 1, and a third encapsulation layer 73 located at a side of the second encapsulation layer 72 away from the base plate 1, and the first encapsulation layer 71, the second encapsulation layer 72, and the third encapsulation layer 73 may include an inorganic material or an organic material. Specifically, the inorganic material may be silicon nitride, silicon oxide, and silicon nitride oxide, etc., and formed by Chemical Vapor Deposition (CVD) process. The organic material may be made of resin or a polymeric organic material, and formed by Inkjet printing (IJP) process. Optionally, the first encapsulation layer 71 and the third encapsulation layer 73 include an inorganic material, and the second encapsulation layer 72 include an organic material.

The embodiments of the present application further provide a method for manufacturing a display panel, including:
S110: providing a base plate;
S120: forming an isolation structure at a side of the base plate, the isolation structure enclosing and forming a plurality of define openings, the define openings including first openings and second openings, the isolation structure including a first portion and a second portion that are stacked, the first portion being arranged at a side of the second portion close to the base plate, an orthographic projection of the first portion on the base plate being located within an orthographic projection of the second portion on the base plate, the second portion including a partition edge, an orthographic projection of the partition edge on the base plate being located at an edge of the orthographic projection of the second portion on the base plate, and the partition edge including a first edge defining the first opening and a second edge defining the second opening; and
S130: forming a light-emitting functional layer and a plurality of first electrodes, the light-emitting functional layer including a plurality of first light-emitting portions and a plurality of second light-emitting portions, at least a portion of the first light-emitting portion being arranged within the first opening, and at least a portion of the second light-emitting portion being arranged within the second opening; and the plurality of first electrodes including a first electrode portion and a second electrode portion arranged at a side corresponding to the second light-emitting portion, a shortest connecting line between an edge of the first electrode portion and the first edge being a first connecting line, a shortest connecting line between an edge of the second electrode portion and the second edge being a second connecting line, and an angle between the second connecting line and a plane in which the base plate is located being less than an angle between the first connecting line and the plane in which the base plate is located.

The method for manufacturing a display panel according to the embodiments of the present application is described below.

In S110, the base plate may be specifically prepared by processes such as coating, curing, and film forming. The base plate may be a rigid base plate such as a glass base plate, or a flexible base plate which may be made of polyimide, polystyrene, polyethylene terephthalate, parylene, polyethersulfone, or polyethylene naphthalate. The base plate is mainly configured to support devices arranged thereon.

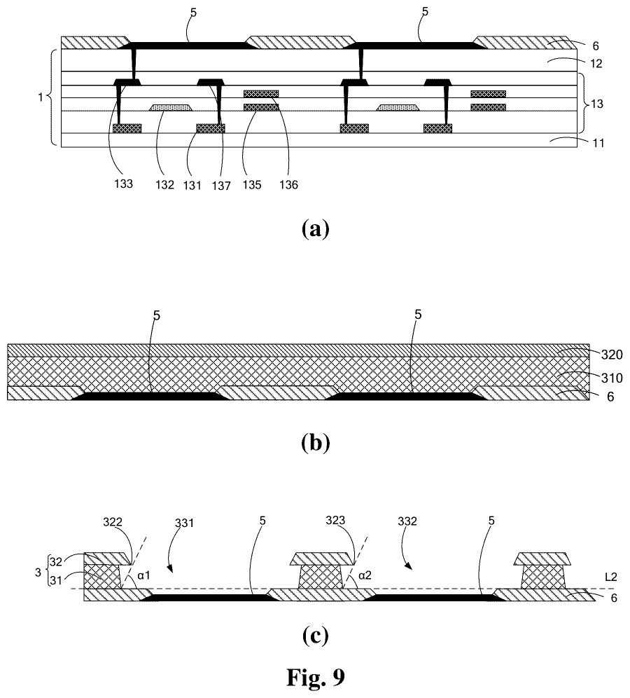

In S120, in order to form the isolation structure, a first portion of material layer 310 and a second portion of material layer 320 may be first formed in sequence at a side of the base plate, as shown in FIG. 9(b), and then the second portion of material layer 320 may be etched to form the second portion 32 and the first portion 31, as shown in FIG. 9(c).

Specifically, at least one of a dry etching or a wet etching may be used to etch and remove the first portion of material layer 310 and the second portion of material layer 320, respectively. It may be understood that the specific materials of the first portion of material layer 310 and the second portion of material layer 320 are etched using corresponding etching solvents, which are not limited herein.

In S130, the film layers of the light-emitting functional layer such as an electron injection layer, an electron transmission layer, a hole blocking layer, a light-emitting material layer, an electron blocking layer, a hole transmission layer, and a hole injection layer, as well as the first electrode, may be formed by vapor deposition process.

In some embodiments, S130 includes:
S210: arranging a first light-emitting material within each of the define openings, vaporizing a first electrically conductive material at a first vaporizing angle, the first electrically conductive material being stacked at a side of the first light-emitting material;
S220: removing the first light-emitting material and the first electrically conductive material within the second openings to expose a second electrode from the define opening, the second electrode being located at a side of the light-emitting functional layer close to the base plate;
S230: arranging a second light-emitting material within each of the define openings, vaporizing a second electrically conductive material at a second vaporizing angle, the second electrically conductive material being stacked at a side of the second light-emitting material, the first vaporizing angle being less than the second vaporizing angle; and
S240: removing the second light-emitting material and the second electrically conductive material within the first openings.

In the embodiments of the present application, the first light-emitting portion and the first electrode portion are first prepared, then the second light-emitting portion and the second electrode portion are prepared, and the first electrode portion and the second electrode portion are vapor deposited using different vaporizing angles, so as to avoid the technical problem that if the first portion is vapor deposited using the same vaporizing angle, the removing process in S220 etches a portion of the first portion, which causes poor overlapping between the first electrode prepared subsequently and the first electrode. The first electrode portion and the second electrode portion are vapor deposited using different vaporizing angles, so that the first portion overlaps the edge of the first electrode, thereby improving the yield of the display panel.

The first electrically conductive material in S210 and the second electrically conductive material in S230 may be the same to simplify the preparation steps. The first light-emitting material and the first electrically conductive material located within the first opening form the first light-emitting portion and the first electrode portion, respectively, and the second light-emitting material and the second electrically conductive material located within the second opening form the second light-emitting portion and the second electrode portion, respectively. If there are two or more light-emitting portions emitting lights of different colors, with reference to S210 to S240, in third, fourth, fifth openings, and so on, different light-emitting materials may be further vapor deposited and electrically conductive materials are vapor deposited using vaporizing angles that are progressively increased step by step, and one light-emitting material and one electrically conductive material are retained within the define opening through removing process.

In some embodiments, the method for manufacturing a display panel may further include, after S210: covering a side of the first electrically conductive material away from the base plate with a first encapsulation material; S220 includes: removing the first encapsulation material, the first light-emitting material, and the first electrically conductive material within the second opening to expose the second electrode from the define opening; the method for manufacturing a display panel may further include, after S230: covering a side of the second electrically conductive material away from the base plate with a second encapsulation material; and S240 includes: removing the second light-emitting material, the second electrically conductive material, and the second encapsulation material located at a side of the first electrically conductive material away from the base plate.

Exemplarily, referring to FIG. 9(a), a second electrode 5 and a pixel defining layer 6 are arranged on the base plate 1, and the second electrode 5 is exposed from the pixel defining layer 6; and referring to FIG. 9(b), the base plate 1 is not shown to facilitate illustration. A first portion of material layer 310 and a second portion of material layer 320 are arranged on the base plate 1 to cover the second electrode 5 and the pixel defining layer 6; referring to FIG. 9(c), the first portion of material layer 310 and the second portion of material layer 320 are patterned to obtain an isolation structure 3, the first portion of material layer 310 arranged on the base plate 1 forms a first portion 31, and the second portion of material layer 320 arranged on the base plate 1 forms a second portion 32. An orthographic projection of the first portion 31 of the isolation structure 3 on the base plate 1 is located within an orthographic projection of the second portion 32 on the base plate 1, the isolation structure 3 encloses and forms a plurality of define openings 33, and the second electrode 5 is exposed from the define opening 33. A connecting line between the edge of an end of the first portion 31 connected with the pixel defining layer 6 and the partition edge is a reference line, the dashed line L2 in FIG. 9(c) shows the plane in which the pixel defining layer 6 is located, and the angle between the plane and the reference line is a. The degrees of the angles α corresponding to the various first portions 31 are substantially the same. For example, α1=α2, as shown in FIG. 9(c).

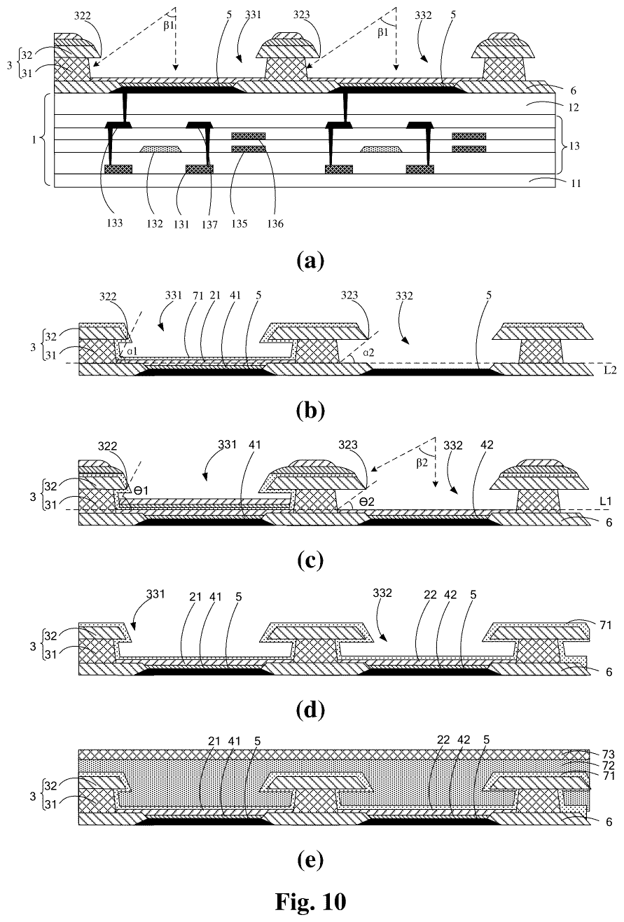

Referring to FIG. 10(a), sequentially, a first light-emitting material is vaporized, a first electrically conductive material is vaporized, and a first encapsulation material is deposited, in which the first electrically conductive material is vaporized at a first vaporizing angle β1 to prepare the first electrode portion 21. The light-emitting material layer, the electrically conductive material layer, and the encapsulation material layer are formed in each of a plurality of define openings 33 including a first opening 331 and a second opening 332, and a portion of the first light-emitting material, the first electrically conductive material, and the first encapsulation material are stacked on the second portion 32, and at this stage, α1 remains the same as α2; referring to FIG. 10(b), the first light-emitting material, the first electrically conductive material, and the first encapsulation material within the second opening 332 and on the second portion 32 are removed, such that a portion of the second electrode 5 is exposed from the second opening 332. The removing process may be an etching process, and when the first light-emitting material, the first electrically conductive material, and the first encapsulation material within the second opening 332 are etched, a portion of the first portion 31 is etched, and thus α1>α2; referring to FIG. 10(c), sequentially, a second light-emitting material is vaporized, a second electrically conductive material is vaporized, and a second encapsulation material is deposited, in which the second electrically conductive material is vaporized at a second vaporizing angle β2 to prepare the second electrode portion 22, and β2>β1. The second light-emitting material layer, the second electrically conductive material layer, and the second encapsulation material layer are formed in each of a plurality of define openings 33 including the first opening 331 and the second opening 332, and a portion of the second light-emitting material, the second electrically conductive material, and the second encapsulation material are stacked on the second portion 32, resulting in that an angle θ2 between a second connecting line and a plane in which the base plate 1 is located is less than an angle θ1 between a first connecting line and the plane in which the base plate 1 is located; referring to FIG. 10(d), the second light-emitting material, the second electrically conductive material, and the second encapsulation material within the first opening 331 and on the second portion 32 are removed. The first light-emitting material within the first opening 331 forms a first light-emitting portion 41, the first electrically conductive material forms a first electrode portion 21, and the first encapsulation material forms a first encapsulation layer 71 located at one side of the first electrode portion 21; the second light-emitting material within the second opening 332 forms a second light-emitting portion 42, the second electrically conductive material forms a second electrode portion 22, and the second encapsulation material forms a first encapsulation layer 71 located at two sides of the second electrode portion 22. Referring to FIG. 10(e), after the light-emitting functional layer, the first electrode, and the first encapsulation layer 71 being prepared, third and fourth encapsulation materials covering the first encapsulation layer 71 are then arranged to form a second encapsulation layer 73 and a third encapsulation layer 74, respectively.

The embodiments of the third aspect of the present application further provide a display apparatus including the display panel according to any of the above embodiments of the first aspect, or a display panel manufactured according to any of the above embodiments of the second aspect. Since the display apparatus according to the embodiments of the third aspect of the present application includes the display panel according to any of the above embodiments of the first aspect or the second aspect, the display apparatus according to the embodiments of the third aspect of the present application has the beneficial effect of the display panel according to any of the above embodiments of the first aspect or the second aspect, which will not be repeated herein.

The display apparatus according to the embodiments of the present application can be applied to a cellular phone or any electronic product with display function, including, but not limited to: a television, a laptop computer, a desktop display screen, a tablet computer, a digital camera, a smart bracelet, smart glasses, an on-board display screen, a medical device, an industrial control device, a touch interaction terminal, etc., which is not specifically limited in the embodiments of the present application.

The above provides only specific implementation of the present application, it is clearly understood by those skilled in the art that for convenience and brevity of the description, specific working processes of the above systems, modules and units can be referred to the corresponding processes in the foregoing embodiments of the method, and will not be repeated herein. It should be understood that the scope of protection of the present application is not limited thereto, and any person skilled in the art can readily think of various equivalent modifications or substitutions within the scope of the technology disclosed in the present application, all of which shall be encompassed within the scope of protection of the present application.

It should be further noted that the exemplary embodiments described in the present application describe some methods or systems based on a series of steps or apparatus. However, the present application is not limited to the order of the steps as described above, i.e., the steps may be performed in the order described in the embodiments or in a different order from that in the embodiments, or some steps may be performed simultaneously.

What is claimed is:

1. A display panel, comprising:
a base plate;
an isolation structure arranged at a side of the base plate, the isolation structure enclosing and forming a plurality of define openings, the plurality of define openings comprising a first opening and a second opening, the isolation structure comprising a first portion and a second portion that are stacked, the first portion being arranged at a side of the second portion close to the base plate, an orthographic projection of the first portion on the base plate being located within an orthographic projection of the second portion on the base plate, the second portion comprising a partition edge, an orthographic projection of the partition edge on the base plate being located at an edge of the orthographic projection of the second portion on the base plate, and the partition edge comprising a first edge defining the first opening and a second edge defining the second opening;
a light-emitting functional layer comprising a plurality of first light-emitting portions and a plurality of second light-emitting portions, at least a portion of the first light-emitting portion being arranged within the first opening, and at least a portion of the second light-emitting portion being arranged within the second opening; and
a plurality of first electrodes located at a side of the light-emitting functional layer away from the base plate, an edge of the first electrode overlapping a side surface of the first portion facing the define opening, the plurality of first electrodes comprising a first electrode portion arranged at a side corresponding to the first light-emitting portion and a second electrode portion arranged at a side corresponding to the second light-emitting portion, a shortest connecting line between an edge of the first electrode portion and the first edge being a first connecting line, a shortest connecting line between an edge of the second electrode portion and the second edge being a second connecting line, and an angle between the second connecting line and a plane in which the base plate is located being less than an angle between the first connecting line and the plane in which the base plate is located.

2. The display panel according to claim 1, wherein the plurality of define openings further comprise a third opening, the light-emitting functional layer further comprises a plurality of third light-emitting portions, at least a portion of the third light-emitting portion is arranged within the third opening, and the partition edge further comprises a third edge defining the third opening; and
the plurality of first electrodes comprise a third electrode portion arranged at a side corresponding to the third light-emitting portion, a shortest connecting line between an edge of the third electrode portion and the third edge is a third connecting line, and an angle between the third connecting line and the plane in which the base plate is located is less than the angle between the second connecting line and the plane in which the base plate is located.

3. The display panel according to claim 1, wherein a minimum distance between an orthographic projection of the first edge on the base plate and the orthographic projection of the first portion on the base plate is H1, a minimum distance between an orthographic projection of the second edge on the base plate and the orthographic projection of the first portion on the base plate is H2, and H1<H2.

4. The display panel according to claim 1, wherein in a direction perpendicular to the plane in which the base plate is located, a cross-section of the second portion is a trapezoid in shape.

5. The display panel according to claim 1, wherein an area of an orthographic projection of a surface of the second portion away from the base plate on the base plate is less than an area of an orthographic projection of a surface of the second portion close to the base plate on the base plate.

6. The display panel according to claim 1, wherein the partition edge is a periphery of the surface of the second portion close to the base plate.

7. The display panel according to claim 1, wherein in a direction perpendicular to the plane in which the base plate is located, a cross-section of the first portion is a trapezoid in shape.

8. The display panel according to claim 1, wherein an area of an orthographic projection of a surface of the first portion away from the base plate on the base plate is less than the area of the orthographic projection of the surface of the second portion close to the base plate on the base plate.

9. The display panel according to claim 1, wherein
the first portion has a single-layer metal structure; or
the first portion has a multi-layer metal structure, and the edge of the first electrode overlaps the multi-layer metal structure.

10. The display panel according to claim 1, wherein the first portion comprises aluminum.

11. The display panel according to claim 1, wherein the first portion comprises a first sub-portion and a second sub-portion that are stacked, the second sub-portion is arranged at a side of the first sub-portion away from the base plate, the first sub-portion comprises molybdenum or titanium, and the second sub-portion comprises aluminum.

12. The display panel according to claim 1, wherein the first portion comprises a first sub-portion and a second sub-portion that are stacked, the second sub-portion is arranged at a side of the first sub-portion away from the base plate, the first sub-portion comprises molybdenum and titanium, and the second sub-portion comprises aluminum.

13. The display panel according to claim 1, wherein the display panel further comprises a pixel defining layer arranged between the base plate and the isolation structure, the pixel defining layer comprises a plurality of pixel openings, and an orthographic projection of the pixel opening on the base plate is located within an orthographic projection of the define opening on the base plate.

14. The display panel according to claim 13, wherein the isolation structure is arranged at a side of the pixel defining layer away from the base plate, and the light-emitting functional layer is at least partially arranged within the pixel openings.

15. The display panel according to claim 1, wherein the display panel further comprises a first encapsulation layer covering a side of the first electrode away from the base plate.

16. A method for manufacturing a display panel, comprising:
providing a base plate;
forming an isolation structure at a side of the base plate, the isolation structure enclosing and forming a plurality of define openings, the define openings comprising a plurality of first openings and a plurality of second openings, the isolation structure comprising a first portion and a second portion that are stacked, the first portion being arranged at a side of the second portion close to the base plate, an orthographic projection of the first portion on the base plate being located within an orthographic projection of the second portion on the base plate, the second portion comprising a partition edge, an orthographic projection of the partition edge on the base plate being located at an edge of the orthographic projection of the second portion on the base plate, and the partition edge comprising a first edge defining the first opening and a second edge defining the second opening; and
forming a light-emitting functional layer and a plurality of first electrodes, the light-emitting functional layer comprising a first light-emitting portion and a second light-emitting portion, at least a portion of the first light-emitting portion being arranged within the first opening, and at least a portion of the second light-emitting portion being arranged within the second opening; and the first electrodes are located at a side of the light-emitting functional layer away from the base plate, an edge of the first electrode overlapping a side surface of the first portion facing the define opening, the plurality of first electrodes comprising a first electrode portion arranged at a side corresponding to the first light-emitting portion and a second electrode portion arranged at a side corresponding to the second light-emitting portion, a shortest connecting line between an edge of the first electrode portion and the first edge being a first connecting line, a shortest connecting line between an edge of the second electrode portion and the second edge being a second connecting line, and an angle between the second connecting line and a plane in which the base plate is located being less than an angle between the first connecting line and the plane in which the base plate is located.

17. The method according to claim 16, wherein the forming the light-emitting functional layer and the first electrodes comprises:
arranging a first light-emitting material within each of the define openings, vaporizing a first electrically conductive material at a first vaporizing angle, the first electrically conductive material being stacked at a side of the first light-emitting material;
removing the first light-emitting material and the first electrically conductive material within the second openings to expose a second electrode from the define opening, the second electrode being located at a side of the light-emitting functional layer close to the base plate;
arranging a second light-emitting material within each of the define openings, vaporizing a second electrically conductive material at a second vaporizing angle, the second electrically conductive material being stacked at a side of the second light-emitting material, the first vaporizing angle being less than the second vaporizing angle; and
removing the second light-emitting material and the second electrically conductive material within the first openings.

18. The method according to claim 16, wherein the plurality of define openings further comprise a third opening, the light-emitting functional layer further comprises a plurality of third light-emitting portions, at least a portion of the third light-emitting portion is arranged within the third opening, and the partition edge further comprises a third edge defining the third opening.

19. The method according to claim 18, wherein the plurality of first electrodes comprise a third electrode portion arranged at a side corresponding to the third light-emitting portion, a shortest connecting line between an edge of the third electrode portion and the third edge is a third connecting line, and an angle between the third connecting line and the plane in which the base plate is located is less than the angle between the second connecting line and the plane in which the base plate is located.

20. A display apparatus comprising the display panel according to claim 1.
